(19) United States
(12) Patent Application Publication
(10) Pub. No.: US 2026/0236066 A1
(43) Pub. Date: Aug. 13, 2026

(54) FLEXIBLE DISPLAY DEVICE, WEARABLE DEVICE, AND MANUFACTURING METHOD FOR FLEXIBLE DISPLAY DEVICE

(71) Applicant: BOE Technology Group Co., Ltd., Beijing (CN)

(72) Inventors: Lijuan ZHAO, Beijing (CN); Hong ZHU, Beijing (CN); Youqing SHEN, Beijing (CN); Yue CUI, Beijing (CN)

(73) Assignee: BOE Technology Group Co., Ltd., Beijing (CN)

(21) Appl. No.: 19/117,716

(22) PCT Filed: Aug. 28, 2024
(86) PCT No.: PCT/CN2024/115186

§ 371 Date: Apr. 2, 2025

(30) Foreign Application Priority Data
Sep. 28, 2023 (CN) 202311279937.2

(51) Int. Cl. G06F 1/16

(52) U.S. Cl. CPC G06F 1/163; G06F 1/1652; G06F 1/1656

(57) ABSTRACT

A flexible display device includes a flexible display panel, where the flexible display panel is provided with a display area and a peripheral area, the peripheral area is provided at a periphery of the display area in a surrounding manner, and a fanout area is provided at a side of the peripheral area away from the display area along a first direction; a sealing structure, wrapped around an edge of the flexible display panel; and a transition layer, wrapped around an exterior of the fanout area, where the transition layer is provided between the fanout area and the sealing structure.

### CROSS-REFERENCE

The present application claims the priority to the Chinese Invention Patent Application No. 202311279937.2, entitled “FLEXIBLE DISPLAY DEVICE, WEARABLE DEVICE, AND MANUFACTURING METHOD FOR FLEXIBLE DISPLAY DEVICE”, filed on Sep. 28, 2023, and the entire contents of which are incorporated herein in their entities.

### TECHNICAL FIELD

The present disclosure relates to the field of display technologies, and specifically to a flexible display device, a wearable device, and a manufacturing method for a flexible display device.

### BACKGROUND

A wearable device has a near field communication (NFC), an embedded subscriber identity module (eSIM), a blood oxygen detection function, and a heart rate detection function, etc., where the NFC is located between a display side and a circuit board, and is not affected by a metal material.

If the wearable device needs to be constantly bent and unfolded during use, it is not possible to give consideration to waterproofing, sealing and use performance of bending.

It should be noted that the information disclosed in the above background section is only used for enhancement of understanding of the background of the present disclosure, and thus may include information that does not constitute prior art known to those ordinary skilled in the art.

### SUMMARY

An object of the present disclosure is to overcome the deficiencies of the prior art describe above, and provide a flexible display device, a wearable device, and a manufacturing method for a flexible display device, which give consideration to waterproofing, sealing, and use performance of bending.

The present disclosure adopts the following technical solutions to achieve the above invention purpose.

According to a first aspect of the present disclosure, there is provided a flexible display device, including:
a flexible display panel, where the flexible display panel is provided with a display area and a peripheral area, the peripheral area is provided at a periphery of the display area in a surrounding manner, and a fanout area is provided at a side of the peripheral area away from the display area along a first direction;
a sealing structure, wrapped around an edge of the flexible display panel; and
a transition layer, wrapped around an exterior of the fanout area, where the transition layer is provided between the fanout area and the sealing structure.

In an exemplary embodiment of the present disclosure, a modulus of the transition layer is less than a modulus of a portion of the sealing structure corresponding to the fanout area; and/or
a thickness of the transition layer is less than a thickness of a portion of the sealing structure corresponding to the fanout area.

In an exemplary embodiment of the present disclosure, the modulus of the transition layer is 0.5 Mpa to 3 Mpa, and the modulus of the portion of the sealing structure corresponding to the fanout area is 3 Mpa to 10 Mpa; and/or
the thickness of the transition layer is 0.05 mm to 0.3 mm, and a sum of the thickness of the portion of the sealing structure corresponding to the fanout area and the thickness of the transition layer is 0.3 mm to 0.5 mm.

In an exemplary embodiment of the present disclosure, a number of the transition layer is multiple, and moduli of a plurality of transition layers are gradually increased along the first direction and along a direction from the fanout area to the sealing structure; and/or
a number of the transition layer is multiple, and thicknesses of a plurality of transition layers are gradually increased along the first direction and along a direction from the fanout area to the sealing structure.

In an exemplary embodiment of the present disclosure, the transition layer includes a thermoplastic-type material of a polyacrylate type.

In an exemplary embodiment of the present disclosure, the flexible display device further includes:
a protective layer, wrapped around the exterior of the fanout area, where the protective layer is provided between the fanout area and the transition layer.

In an exemplary embodiment of the present disclosure, an end area is provided at a side of the flexible display panel away from the fanout area along the first direction, the display area includes a bending region and a non-bending region, and the bending region and the non-bending region are arranged along the first direction; and
an adjusting gap is provided between the end area and the sealing structure.

In an exemplary embodiment of the present disclosure, the adjusting gap is positively correlated with a length of the bending region, the adjusting gap is positively correlated with a bending angle of the bending region, and the adjusting gap is negatively correlated with a bending radius of the bending region.

In an exemplary embodiment of the present disclosure, a groove is provided at a side of the sealing structure facing the end area.

In an exemplary embodiment of the present disclosure, the display area includes a bending region and a non-bending region, and the bending region and the non-bending region are arranged along the first direction; and
the sealing structure includes:
   a first sealing part, provided at at least one side of the display area along a second direction, where the first sealing part is provided in correspondence with the bending region, and the second direction is perpendicular to the first direction; and
   a second sealing part, provided at at least one side of the display area along the second direction, where the second sealing part is provided in correspondence with the non-bending region;
where a modulus of the first sealing part is less than a modulus of the second sealing part; and/or a thickness of the first sealing part is less than a thickness of the second sealing part.

In an exemplary embodiment of the present disclosure, the modulus of the first sealing part is 0 to 3 Mpa, and the modulus of the second sealing part is 3 Mpa to 20 Mpa; and/or
the thickness of the first sealing part is 0.05 mm to 0.1 mm, and the thickness of the second sealing part is 0.1 mm to 0.2 mm.

In an exemplary embodiment of the present disclosure, a tensile strength of the first sealing part is ≥12 Mpa, an elongation at break of the first sealing part is ≥110%, and a surface adhesivity of the first sealing part is ≥5 Mpa.

In an exemplary embodiment of the present disclosure, the sealing structure includes an organopolysiloxane polymer-type material, a silica filler, a silane adhesion promoter, and a catalyst; or
the sealing structure includes at least one of an epoxy resin type, a polyurethane type, an acrylic acid type, and an ethylene-vinyl acetate copolymer.

In an exemplary embodiment of the present disclosure, the fanout area includes a bending part and a connecting part, one end of the bending part is connected to the display area, another end of the bending part is connected to the connecting part, the bending part and the connecting part are arranged along a third direction, and the third direction, the first direction and the second direction are perpendicular to each other respectively;
the flexible display device further includes a supporting layer, and the supporting layer is provided between the display area and the connecting part; and
an activity cavity is formed between a side of the supporting layer and a side of the fanout area that are close to each other.

In an exemplary embodiment of the present disclosure, the flexible display panel further includes:
a cover layer, provided at a side of the display area away from the connecting part along the third direction;
where an orthographic projection of the cover layer relative to the display area is located outside an orthographic projection of the sealing structure relative to the display area, and the orthographic projection of the cover layer relative to the display area is located outside an orthographic projection of the transition layer relative to the display area.

According to another aspect of the present disclosure, there is provided a wearable device that includes the flexible display device described above.

According to yet another aspect of the present disclosure, there is provided a manufacturing method for a flexible display device, used for manufacturing the flexible display device describe above, where the manufacturing method for the flexible display device includes steps of:
bending the fanout area of the flexible display panel to a backlight side of the display area;
wrapping the transition layer around the exterior of the fanout area; and
wrapping the sealing structure around the edge of the flexible display panel and around an exterior of the transition layer.

In the flexible display device, the wearable device, and the manufacturing method for a display device provided in the present disclosure, the sealing structure is provided at the periphery of the flexible display device in a surrounding manner, thereby sealing the peripheral side of the flexible display panel and providing waterproof and oilproof functions. The transition layer provides intermediate transition and gradation functions between the fanout area and the sealing structure, and the transition layer also achieves the function of isolation between the fanout area and the sealing structure to a certain extent, avoiding the direct contact between the fanout area and the sealing structure, and reducing the occurrence of failure of the flexible display panel in the bending process.

It should be understood that the above general description and the later detailed description are merely exemplary and explanatory, and cannot limit the present disclosure.

### BRIEF DESCRIPTION OF THE DRAWINGS

The accompanying drawings herein are incorporated into the specification and form a portion of the specification, illustrate embodiments consistent with the present disclosure, and are used in conjunction with the specification to explain the principles of the present disclosure. It is apparent that the accompanying drawings in the following description are only some of the embodiments of the present disclosure, and other accompanying drawings may be obtained based on these accompanying drawings without creative labor for those ordinary skilled in the art.

FIG. 1 is a schematic diagram I of a structure of an existing wearable device.

FIG. 2 is a schematic diagram II of a structure of an existing wearable device.

FIG. 3 is a schematic diagram III of a structure of an existing wearable device.

FIG. 4 is a schematic diagram IV of a structure of an existing wearable device.

FIG. 5 is a schematic diagram V of a structure of an existing wearable device.

FIG. 6 is a schematic diagram VI of a structure of an existing wearable device.

FIG. 7 is a schematic diagram of a structure of a flexible display panel of a flexible display device in an embodiment of the present invention.

FIG. 8 is a schematic diagram of a structure of a flexible display device in an embodiment of the present invention.

FIG. 9 is a cross-sectional view of a flexible display device in an embodiment of the present invention.

FIG. 10 is a cross-sectional view at a fanout area of a flexible display device in an embodiment of the present invention.

FIG. 11 is a partially enlarged view of FIG. 9 at A.

FIG. 12 is a cross-sectional view at a fanout area of another form of a flexible display device in an embodiment of the present invention.

FIG. 13 is a cross-sectional view at an end area of another form of a flexible display device in an embodiment of the present invention.

FIG. 14 is a cross-sectional view at a fanout area of a further form of a flexible display device in an embodiment of the present invention.

FIG. 15 is a schematic diagram of a structure of a wearable device in a non-bending state in an embodiment of the present invention.

FIG. 16 is a schematic diagram of a structure of a wearable device in a bent state in an embodiment of the present invention.

FIG. 17 is a schematic diagram of a flexible display device during adhesive dispensing in an embodiment of the present invention.

Reference numerals: 101, waterproof resin; 102, center frame; 105, cover plate; 106, display panel; 201, chain knot; 202, resistance mechanism; 203, sliding groove;
100, wearable device; 200, barrel;
1, flexible display panel; 11, display area; 111, bending region; 112, non-bending region; 12, peripheral area; 13, fanout area; 131, bending part; 132, connecting part; 14, end area;
2, sealing structure; 21, first sealing part; 22, second sealing part;
3, transition layer;
4, protective layer;
5, adjusting gap;
6, supporting layer; 61, first supporting sub-layer; 62, second supporting sub-layer; 63, gasket layer;
7, cover layer; 71, cover plate; 72, polarizer;
8, SCF layer;
9, decorative layer;
10, activity cavity.

### DETAILED DESCRIPTION

Exemplary embodiments are now described more comprehensively with reference to the accompanying drawings. However, the exemplary embodiments are capable of being implemented in a variety of forms, and should not be construed as being limited to the embodiments set forth herein. Although relative terms such as “up” and “down” are used in this specification to describe a relative relationship between one component and another component indicated in the drawings, these terms are used in this specification only for convenience, e.g., in accordance with the direction of the example described in the accompanying drawings. It can be understood that if the device indicated in the drawing is flipped upside down, the component described as being “up” will become the component described as being “down”. Other relative terms such as “top” and “bottom” have similar meanings. When a certain structure is “on” another structure, it may mean that the certain structure is integrally formed on the another structure, or that the certain structure is “directly” arranged on the another structure, or that the certain structure is “indirectly” arranged on the another structure through yet another structure.

The terms “a”, “an”, “the”, and “said” are used for indicating an existence of one or more elements/components/etc.; and the terms “include” and “have” are used for indicating an open-ended inclusion and mean that there may be additional elements/components/etc. in addition to the listed elements/components/etc. The terms “first”, “second”, etc. are used merely as markers but not as number limitations to the objects thereof.

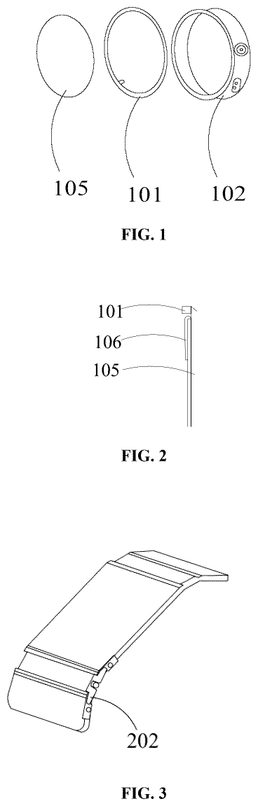

As shown in FIGS. 1-2, a size of a cover plate 105 of an existing wearable device is larger than a size of a display panel 106, a circle of waterproof resin 101 is added to an edge part of the cover plate 105 that protrudes from the display panel 106, a side of the waterproof resin 101 is fixed to the cover plate 105, another side of the waterproof resin 101 is fixed to a center frame 102, and the display panel 106 is wrapped inside the center frame 102, forming a sealed waterproof structure.

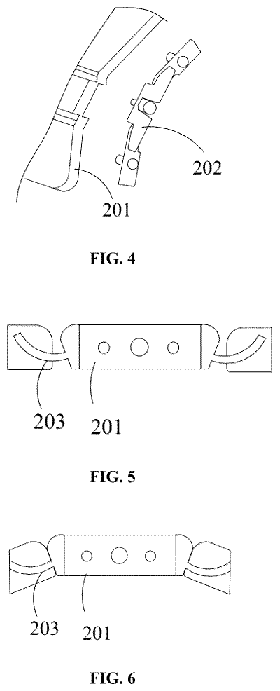

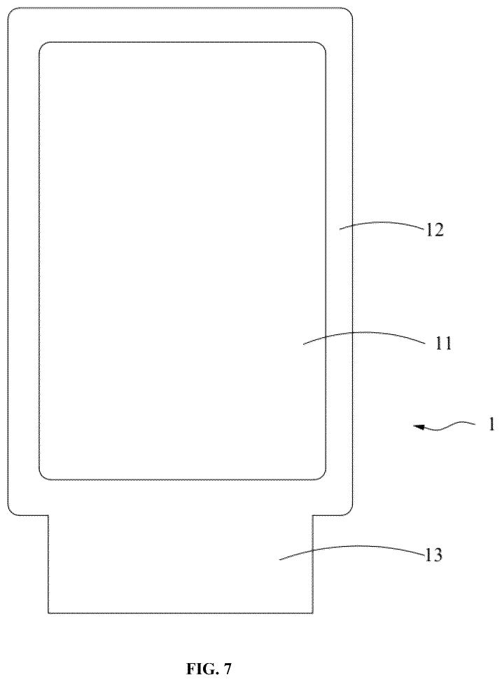

The existing wearable device has gradually expanded to a flexible product, and a hinge structure is added to the wearable device. The hinge structure corresponds to a bending region of the display panel, which can meet the bending and unfolding requirements. Specifically, as shown in FIGS. 3-6, the hinge structure includes chain knots, where the chain knots include a first chain knot 201, a second chain knot 201, and a third chain knot 201 arranged at intervals, and the second chain knot 201 and the third chain knot 201 are movable in a bending manner along a slot 203. A resistance mechanism 202 is composed of a disc spring, which serves as an external torsion area and provides a resistance for bending, preventing the display panel from being damaged through bending too fast.

The embodiment provides a flexible display device, as shown in FIGS. 7-8, the flexible display device includes a flexible display panel 1 and a sealing structure 2. The flexible display panel 1 is provided with a display area 11 and a peripheral area 12. The peripheral area 12 is provided at a periphery of the display area 11 in a surrounding manner. A fanout area 13 is provided at a side of the peripheral area 12 away from the display area 11 along a first direction D1 (where the first direction is identified with D1, and the first direction specifically refers to a length direction of the flexible display panel 1).

A Pad Bending technology is used in the flexible display panel 1. After a test of the flexible display panel 1 is completed, special-shaped cutting may be perform on a display substrate of the flexible display panel 1 through a laser cutting process to remove a test area of the display substrate, and a fanout area 13 is bent to a back surface of the display substrate, i.e., the fanout area 13 is bent towards a backlight layer of the display area 11, achieving a purpose of reducing a width of a border.

It should be noted that when the fanout area 13 is bent, the display substrate formed with structures such as signal lines is bent, i.e., the structures in the fanout area 13 are consequently bent to the back surface side of the display substrate.

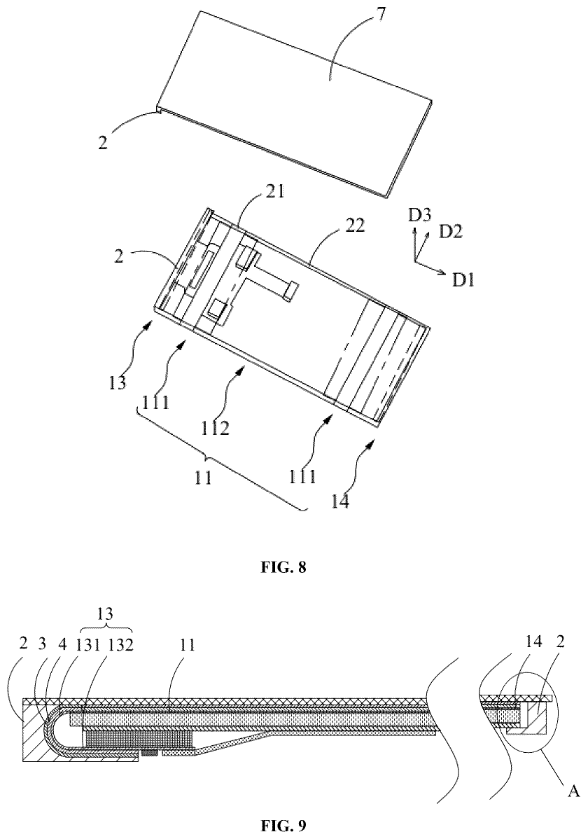

As shown in FIGS. 8-9, the sealing structure 2 is wrapped around an edge of the flexible display panel 1, i.e., the sealing structure 2 is provided at a periphery of the flexible display panel 1 in a surrounding manner to seal a peripheral side of the flexible display panel 1, thereby providing waterproof and oilproof functions.

The display area 11 includes a bending region 111 and a non-bending region 112. The bending region 111 and the non-bending region 112 are arranged along the first direction D1, i.e., the bending region 111 is provided with a plurality of hinges hinged to each other, and a bending direction of the hinge in the bending region 111 is the first direction D1. The flexible display panel 1 needs to be repeatedly bent during use. A texture of the flexible display panel 1 is soft, but a texture of the sealing structure 2 is hard. When the flexible display panel 1 is bent to produce dislocation movement, the flexible display panel 1 with the soft texture is difficult to drive the sealing structure 2 with the hard texture, and the sealing structure 2 provides a certain resistance to the flexible display panel 1, resulting in fracture of the flexible display panel 1.

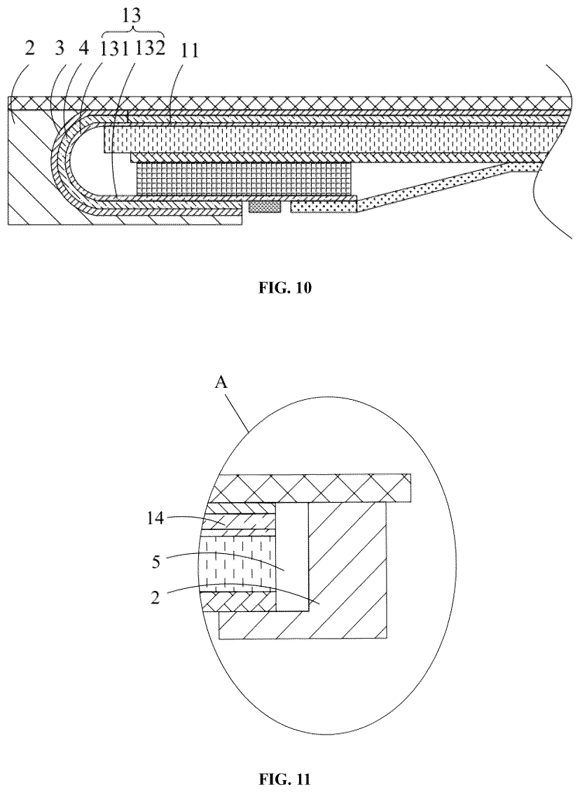

In view of this, as shown in FIGS. 9-10, the flexible display device further includes a transition layer 3. The transition layer 3 is wrapped around an exterior of the fanout area 13. The transition layer 3 is provided between the fanout area 13 and the sealing structure 2.

The transition layer 3 provides intermediate transition and gradation functions between the fanout area 13 and the sealing structure 2, and the transition layer 3 also achieves the function of isolation between the fanout area 13 and the sealing structure 2 to a certain extent, avoiding the direct contact between the fanout area 13 and the sealing structure 2, and reducing the occurrence of failure of the flexible display panel 1 in the bending process.

It should be particularly noted that if the display area 11 is not provided with the bending region 111, i.e., the display area 11 is a rigid structure and does not have a bending function, in this case, the transition layer 3 may likewise provide the intermediate transition and gradation functions between the fanout area 13 and the sealing structure 2, facilitating connection and fixation between the fanout area 13 and the sealing structure 2 of the flexible display panel 1.

In some embodiments, the transition layer 3 includes a thermoplastic-type material of a polyacrylate type, enabling the firm adhesion of the transition layer 3 and enabling the transition layer 3 to be not easily peeled off, and increasing the fixation effect between the transition layer 3 and the fanout area 13; and the transition layer 3 is pliable and elastic at a room temperature, and is capable of matching the flexible display panel 1 with the soft texture. In addition, this type of material also has certain waterproof properties, further improving the sealing effect of the flexible display panel 1.

In an embodiment, a modulus of the transition layer 3 is less than a modulus of a portion of the sealing structure 2 corresponding to the fanout area 13.

In some embodiments, the modulus specifically refers to a ratio of stress to strain of a material under a state of stress. The modulus of the transition layer 3 is relatively small, and the transition layer 3 can produce a large deformation. The modulus of the portion of the sealing structure 2 corresponding to the fanout area 13 is relatively large, and the portion of the sealing structure 2 corresponding to the fanout area 13 produces a small deformation. When the flexible display panel 1 is bent to produce dislocation movement, because the transition layer 3 can produce a large elastic deformation, the flexible display panel 1 can directly drive the transition layer 3, and the transition layer 3 plays a role in following the movement to a certain extent, reducing the risk of failure due to fracture of the flexible display panel 1.

Exemplarily, the modulus of the transition layer 3 is 0.5 Mpa to 3 Mpa, for example, the modulus of the transition layer 3 is 0.5 Mpa, 1 Mpa, 1.5 Mpa, 2 Mpa, 3 Mpa, etc. The modulus of the portion of the sealing structure 2 corresponding to the fanout area 13 is 3 Mpa to 10 Mpa, for example, the modulus of the portion of the sealing structure 2 corresponding to the fanout area 13 is 3 Mpa, 4 Mpa, 7.5 Mpa, 8 Mpa, 10 Mpa, etc.

In an embodiment, a thickness of the transition layer 3 is less than a thickness of the portion of the sealing structure 2 corresponding to the fanout area 13. By using the transition layer 3 with a thin thickness, it is easier for the transition layer 3 to move with the dislocation movement of the flexible display panel 1, improving the tracking effect of the movement of the transition layer 3 with respect to the fanout area 13.

Exemplarily, the thickness of the transition layer 3 is 0.05 mm to 0.3 mm, for example, the thickness of the transition layer 3 is 0.05 mm, 0.18 mm, 0.2 mm, 0.25 mm, and 0.3 mm. A sum of the thickness of the portion of the sealing structure 2 corresponding to the fanout area 13 and the thickness of the transition layer is 0.3 mm to 0.5 mm, for example, the thickness of the portion of the sealing structure 2 corresponding to the fanout area 13 is 0.3 mm, 0.35 mm, 0.4 mm, 0.42 mm, 0.5 mm.

In an embodiment, the number of transition layers 3 is multiple, and moduli of the plurality of the transition layers 3 are gradually increased along the first direction D1 and along a direction from the fanout area 13 to the sealing structure 2; and/or the number of the transition layers 3 is multiple, and thicknesses of the plurality of the transition layers 3 are gradually increased along the first direction D1 and along a direction from the fanout area 13 to the sealing structure 2.

The plurality of the transition layers 3 are sequentially stacked between the fanout area 13 and the sealing structure 2, and the plurality of the transition layers 3 provide a gradual transition function, increasing flexible connection between the fanout area 13 and the sealing structure 2, and further reducing the risk of fracture and failure of the flexible display panel 1.

Therefore, through selection of the material, modulus, thickness, and number of the transition layer 3, when the display area 11 of the flexible display panel 1 is bent at a bending radius of about 5 mm to 10 mm and a bending angle of 60° to 90°, a room-temperature dynamic reliability test is performed on the flexible display panel 1, because the flexible display panel 1 is provided with the transition layer 3, the transition layer 3 can absorb the dislocation movement caused by the bending, and thus reduces the occurrence of poor display problems such as bright dark lines.

Since the fanout area 13 is bent towards the backlight side of the display area 11, the fanout area 13 is prone to fracture during the bending process or has a low structural strength after bending. In view of this, as shown in FIGS. 10-11, the flexible display device further includes a protective layer 4. The protective layer 4 is wrapped around the exterior of the fanout area 13. The protective layer 4 is provided between the fanout area 13 and the transition layer 3. The protective layer 4 is provided in correspondence with the fanout area 13, and is wrapped around the exterior of the fanout area 13, playing a role in protecting the fanout area 13, avoiding damage to the fanout area 13 by the sealing structure 2 with the hard texture, and extending the service life of the fanout area 13.

Since the display area 11 of the flexible display panel 1 is provided with the bending region 111 and the non-bending region 112, the flexible display panel 1 needs to be constantly bent and unfolded during use, and in the repeated bending process, the flexible display panel 1 will have dislocation movement, causing that the flexible display panel 1 cannot give consideration to both the bending performance and the waterproof performance.

In view of this, as shown in FIGS. 9 and 11, an end area 14 is provided at a side of the flexible display panel 1 away from the fanout area 13 along the first direction D1, and an adjusting gap 5 is provided between the end area 14 and the sealing structure 2.

The adjusting gap 5 may also be referred to as the amount of dislocation movement, i.e., the end area 14 and the sealing structure 2 are not completely in contact with each other, but a certain spacing is present between the end area 14 and the sealing structure 2. The adjusting gap 5 is essentially a reserved gap for a tail end of the flexible display panel 1, enabling that the flexible display panel 1 is provided with a certain space for dislocation movement during the bending process of the flexible display panel 1, thereby reducing the occurrence of interference during the bending process, and improving the use reliability of the bending of the flexible display panel 1.

In an embodiment, the adjusting gap 5 is positively correlated with a length of the bending region 111. The adjusting gap 5 is positively correlated with a bending angle of the bending region 111. The adjusting gap 5 is negatively correlated with a bending radius of the bending region 111.

The appropriate adjusting gap 5 is selected according to the length of the bending region 111, the bending angle of the bending region 111, and the bending radius of the bending region 111, ensuring that the flexible display panel 1 is provided with a certain space for dislocation movement during the bending process.

Exemplarily, the bending angle of the bending region 111 is 60° to 90°, for example, the bending angle of the bending region 111 is 60°, 65°, 70°, 80°, 90°, etc. When the bending radius of the bending region 111 is about 5 mm to 10 mm, the adjusting gap 5 is 0.3 mm to 0.5 mm, for example, the adjusting gap 5 is 0.3 mm, 0.35 mm, 0.4 mm, 0.45 mm, 0.5 mm, etc.

In some other embodiments, a groove (not shown in the drawings) is provided at a side of the sealing structure 2 facing the end area 14.

When the flexible display panel 1 is in the process of bending, the end area 14 of the flexible display panel 1 may extend into the groove, and the groove may provide a certain movement space for the flexible display panel 1, enabling that the flexible display panel 1 is provided with a certain space for dislocation movement, and improving the use reliability of the bending of the flexible display panel 1. In some embodiments, along the first direction D1, a depth of the groove may be greater than or equal to the adjusting gap 5.

Therefore, for at least one end of the flexible display panel 1 along the first direction D1, the transition layer 3 and the adjusting gap 5 are provided in correspondence with the fanout area 13 and the end part respectively, and adjust the position where the dislocation movement is concentrated, thereby giving consideration to the waterproof effect while not affecting the bending performance.

In an embodiment, as shown in FIGS. 9-10, the fanout area 13 includes a bending part 131 and a connecting part 132. One end of the bending part 131 is connected to the display area 11, and another end of the bending part 131 is connected to the connecting part 132. The bending part 131 and the connecting part 132 are arranged proximately along the third direction D3 when the flexible display panel 1 is bent from the flattened state to the bent state, and the connecting part 132 is used for binding with a driving chip. In some embodiments, any two of the first direction D1, the second direction D2, and the third direction are perpendicular to each other (the second direction is identified with D2, the second direction D2 is specifically a width direction of the flexible display panel 1, the third direction is identified with D3, and the third direction D3 is specifically a thickness direction of the flexible display panel 1).

It should be particularly noted that the bending part 131 of the fanout area 13 is bent along the third direction D3, the hinge of the bending region is bent along the first direction D1, and the two have differences.

Since the fanout area 13 is provided between the display area 11 and the connecting part 132, a certain height distance is present between the display area 11 and the connecting part 132 along the third direction D3, i.e., the display area 11 is suspended, which makes it difficult to ensure the positional stability of the display area 11.

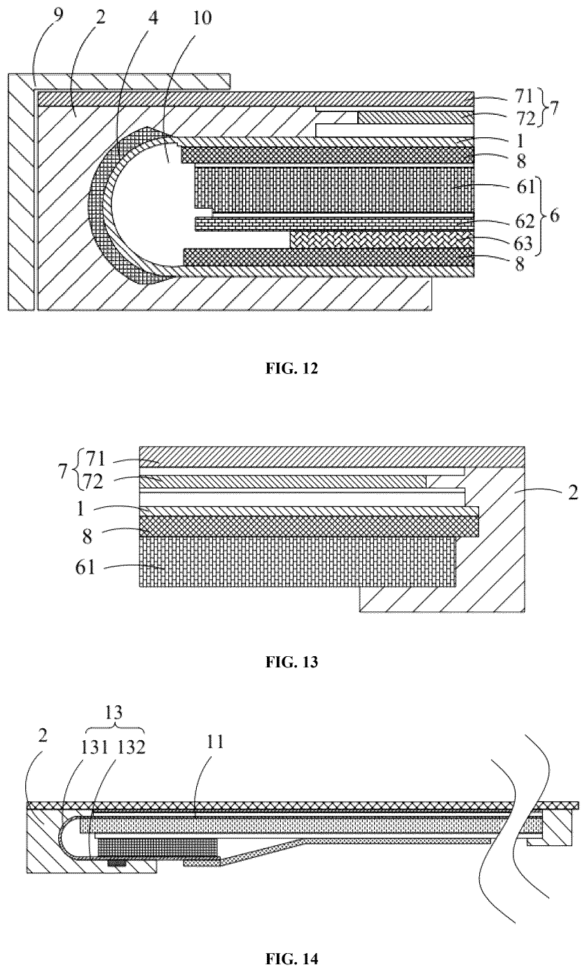

In view of this, as shown in FIG. 12, the flexible display panel 1 further includes a supporting layer 6. The supporting layer 6 is provided between the display area 11 and the connecting part 132.

That is, along the third direction D3, a bottom part of the supporting layer 6 is provided at a side of the connecting part 132 facing the display area 11, and a top part of the supporting layer 6 abuts against a side of the display area 11 facing the connecting part 132. The supporting layer 6 is capable of carrying the display area 11, avoiding the situation where the display area 11 is suspended, and improving the positional stability of the display area 11.

In some embodiments, an activity cavity 10 is formed between a side of the supporting layer 6 and a side of the fanout area 13 that are close to each other. The fanout area 13 and the supporting layer 6 are not tightly in contact with each other, no other waterproof member is filled in the activity cavity 10, and the activity cavity 10 is a cavity structure, i.e., along the first direction D1, a certain distance is present between the supporting layer 6 and the fanout area 13, enabling that the flexible display panel 1 is provided with a certain space for dislocation movement during the bending process of the flexible display panel 1, thereby improving the use reliability of the bending of the flexible display panel 1.

It should be understood that the fanout area 13 is an arc-shaped structure, and plays a role in the smooth transition between the display area 11 and the connecting part 132, then the side of the activity cavity 10 facing the fanout area 13 is also an arc-shaped structure.

Specifically, as shown in FIG. 12, the supporting layer 6 includes a first supporting sub-layer 61 and a second supporting sub-layer 62 that are arranged in a stacking manner. Along the third direction D3, the second supporting sub-layer 62 is provided at a side of the connecting part 132 facing the display area 11. The first supporting sub-layer 61 is provided on the second supporting sub-layer 62. The first supporting sub-layer 61 may directly or indirectly carry the display area 11.

In general, as shown in FIGS. 12-13, a length of the connecting part 132 is less than a length of the display area 11 along the first direction D1, and the display area 11 and the connecting part 132 have overlapping parts along the third direction D3, then a double-layer structure with the first supporting sub-layer 61 and the second supporting sub-layer 62 is provided in the vicinity of the fanout area 13, achieving the support of the area between the connecting part 132 and the display area 11. The first supporting sub-layer 61 is a flat layer structure. In the thickness direction of the flexible display panel 1, the portion of the display area 11 not overlapped with the connecting part 132 is only provided with the first supporting sub-layer 61 as a single-layer supporting structure to support the display area 11.

It should be noted that the supporting layer 6 includes, but is not limited to, the first supporting sub-layer and the second supporting sub-layer 62. The number of the second supporting sub-layers 62 may be multiple. The plurality of the second supporting sub-layers 62 are sequentially stacked and used for adjusting the thickness of the entire supporting layer 6. Other functional layers such as an adhesive layer or a heat dissipation layer may be provided between two adjacent supporting sub-layers 6.

Of course, the supporting layer 6 may further include a gasket layer 63. The gasket layer 63 is provided at the side of the connecting part 132 facing the display area 11. The gasket layer 63 is provided between the connecting part 132 and the supporting layer 6, facilitating the support of the area between the connecting part 132 and the display area 11.

In an embodiment, the flexible display device further includes an SCF layer 8. The SCF layer 8 is located between the supporting layer 6 and the flexible display panel 1. Along a direction away from the flexible display panel 1, the SCF layer 8 includes an adhesive layer, a buffer layer, a supporting sub-layer, and a heat dissipation layer stacked in sequence. The adhesive layer is used for bonding with the flexible display panel 1. The adhesive layer may specifically be selected as a grid adhesive. The buffer layer provides a buffer function. The buffer layer may be selected as a foam. The supporting sub-layer serves as a substrate and provides a supporting function. The supporting sub-layer may be selected as a polyimide. The heat dissipation layer provides a heat dissipation function. The heat dissipation layer may be selected as a copper foil for heat dissipation.

In an embodiment, as shown in FIGS. 12-13, the flexible display panel 1 further includes a cover layer 7. The cover layer 7 is provided at a side of the display area 11 away from the connecting part 132 along the third direction D3. In some embodiments, an orthographic projection of the cover layer 7 relative to the display area 11 is located outside an orthographic projection of the sealing structure 2 relative to the display area 11. The orthographic projection of the cover layer 7 relative to the display area 11 is located outside an orthographic projection of the transition layer 3 relative to the display area 11.

In this way, the coverage range of the cover layer 7 extends from the display area 11 to the transition layer 3 and the sealing structure 2, and the cover layer 7 provides a protective function and is aesthetically pleasing.

Specifically, the cover layer 7 specifically includes a cover plate 71 and a polarizer 72. The polarizer 72 and the cover plate 71 are sequentially stacked on the display area 11 of the flexible display panel 1 along the first direction D1. In some embodiments, the cover plate 71 includes at least one of a polyimide type, a polyethylene terephthalate type, and a triacetate fiber film, and extends along an edge of the cover plate 71 to form an extension part, i.e., the cover plate 71 extends outwardly by 0.3 mm to 0.5 mm, and the sealing structure 2 is just covers the extension part. The sealing structure 2 is wrapped around the flexible display panel 1 along the third direction D3 to achieve the effect of sealing and waterproofing.

In an embodiment, the flexible display device further includes a decorative layer 9. The decorative layer 9 is wrapped around the sealing structure 2 and the cover plate 71 of the cover layer 7 along the first direction DI and the third direction D3 respectively, providing a decorative and aesthetic function.

In an embodiment, the sealing structure 2 includes a first sealing part 21 and a second sealing part 22 (as shown in FIG. 8). The first sealing part 21 is provided at at least one side of the display area 11 along the second direction D2. The second sealing part 22 is provided at at least one side of the display area 11 along the second direction D2.

That is, the first sealing part 21 and the second sealing part 22 may be located at one side or two sides of the display area 11 along the second direction D2 to seal the side wall of the display area 11 along the width direction of the flexible display panel 1. Exemplarily, the first sealing part 21 and the second sealing part 22 are both located at two sides of the display area 11 along the second direction D2, the first sealing part 21 and the second sealing part 22 achieve the sealing of the flexible display panel 1 in the width direction, and the portion of the sealing structure 2 corresponding to the fanout area 13 and the portion of the sealing structure 2 corresponding to the adjusting gap 5 achieve the sealing of the flexible display panel 1 along the first direction D1. In this way, the sealing structure 2 achieves the sealing of the flexible display panel 1 along the circumferential sidewall of the flexible display panel 1.

Specifically, the first sealing part 21 is provided in correspondence with the bending region 111, and the second sealing part 22 is provided in correspondence with the non-bending region 112. Since the bending region 111 needs to be bent and the non-bending region 112 does not need to be bent, and the first sealing part 21 and the second sealing part 22 correspond to the bending region 111 and the non-bending region 112 respectively, the two sealing parts are differentiated with respect to whether or not the position needs to be bent, and waterproofing is performed on the bending region 111 and the non-bending region 112 separately, satisfying the waterproofing while giving consideration to the bending performance requirements.

In some embodiments, a modulus of the first sealing part 21 is less than a modulus of the second sealing part 22. The modulus of the first sealing part 21 is relatively small, and the first sealing part 21 can produce a large deformation. The modulus of the second sealing part 22 is relatively large, and the second sealing part 22 produces a small deformation. When the flexible display panel 1 is bent to produce dislocation movement, because the first sealing part 21 can produce a large elastic deformation, the first sealing part 21 is more easily bent, improving the user's sense of use.

Exemplarily, the modulus of the first sealing part 21 is 0 to 3 Mpa, for example, the modulus of the first sealing part 21 is 0, 1 Mpa, 1.5 Mpa, 2 Mpa, 3 Mpa, etc. The modulus of the second sealing part 22 is 3 Mpa to 20 Mpa, for example, the modulus of the second sealing part 22 is 3 Mpa, 5 Mpa, 8 Mpa, 10 Mpa, 15 Mpa, 20 Mpa.

In some embodiments, a thickness of the first sealing part 21 is less than a thickness of the second sealing part 22. By using the first sealing part 21 with a thin thickness, it is easier for the first sealing part 21 to bend with the bending of the bending region 111 of the flexible display panel 1, improving the tracking effect of the movement of the first sealing part 21 with respect to the bending region 111, and enabling the user to use the bending in a smooth, time-saving and labor-saving manner.

Exemplarily, the thickness of the first sealing part 21 is 0.05 mm to 0.1 mm, for example, the thickness of the first sealing part 21 is 0.05 mm, 0.06 mm, 0.07 mm, 0.08 mm, 0.1 mm, etc. The thickness of the second sealing part 22 is 0.1 mm to 0.2 mm. The thickness of the second sealing part 22 is 0.1 mm, 0.12 mm, 0.15 mm, 0.18 mm, 0.2 mm, etc.

In an embodiment, both the first sealing part 21 and the second sealing part 22 may include a primary ingredient, a filler part, an adhesion promoter part, and a catalyst part. In some embodiments, the primary ingredient is a main component of the original pulp. The filler part is an auxiliary portion of the primary ingredient, and is used for assisting in achieving other functions. The adhesion promoter part is used for increasing adhesivity with the flexible display panel 1. The catalyst is used for increasing a curing effect.

Specifically, the chemical formula of the primary ingredient is specifically X₃₋ₙRₙSi-(Z)_{d}-(O)_{q}-(R′_{y}SiO_{(4-y)/2})_{z}-(SiR′₂-Z)_{d}-Si-RₙX₃₋ₙ, and is specifically an organopoly siloxane polymer-type material having two hydroxyls or hydrolysable. For each group of the molecular formula, each X may be a hydroxyl or a hydrolysable group, each R may be an alkyl, an alkenyl or an aryl group, each R′ is an X group, an alkyl, an alkenyl group and an aryl group, and Z is a divalent organic group. In some embodiments, d is 0 or 1, q is 0 or 1, and d+q=1; and n is 0, 1, 2 or 3, y is 0, 1 or 2, n and y are preferably 2, and z is an integer.

Specifically, according to the waterproof functional use, the filler part may specifically be selected as a silica filler, and hydrophobic treatment is performed on the silica filler to meet the sealing requirements. Exemplarily, the silica filler includes a precipitated silica (wet-method silica), a pyrolyzed-method silica (dry-method silica), a calcined silica, etc., and the silica filler accounts for about 20% to 30% by weight.

Specifically, the adhesion promoter part may be selected as a silane adhesion promoter, and the silane adhesion promoter accounts for about 1% to 2% by weight.

Specifically, the catalyst includes two materials, the first material includes a titanate and/or a zirconate, and the second material includes a metal carboxylate.

The degree of cross-linking, the molecular weight and the intermolecular force of the cured sealing structure 2 are regulated by controlling the composition of each portion of the original pulp, ensuring that the modulus of the first sealing part 21 corresponding to the bending region is ≤3 Mpa, e.g., 1 Mpa, 1.5 Mpa, 1.8 Mpa, 2 Mpa, 3 Mpa, etc., and that the modulus of the second sealing part 22 corresponding to the non-bending region is approximately 3 Mpa to 20 Mpa, e.g., 3 Mpa, 5 Mpa, 10 Mpa, 13 Mpa, 20 Mpa, etc.

In some other embodiments, for the first sealing part 21, d=0, R is an alkenyl-type polymer, X and R′ are hydrocarbyls, and the modulus of the cured first sealing part 21 is ≤3 Mpa; for the second sealing art 22, d=0, X, R′ and Rn are alkenyl-type polymers, and the first sealing part 21 and the second sealing part 22 have the same catalyst content or catalyst weight proportion, or the second sealing part 22 may be increased in the same proportion as desired.

In some other embodiments, for the first sealing part 21, d=0, Rₙ is an alkenyl-type polymer, X and R′ are hydrocarbyls, and the modulus of the cured first sealing part 21 is ≤3 Mpa; for the second sealing part 22, d=0, Rₙ is an alkenyl-type polymer, R′ is an aryl-type polymer, and the first sealing part 21 and the second sealing part 22 have the same catalyst content or catalyst weight proportion, or the second sealing part 22 may be increased in the same proportion as desired.

In some other embodiments, for the first sealing part 21, d=0, Rₙ and X are alkyls, and R′ is an alkenyl-type polymer; and for the second sealing part 22, Rₙ, X and R′ are all alkenyl-type polymers.

In some other embodiments, both the modulus of the first sealing part 21 and the modulus of the second sealing part 22 are ≤3 Mpa, and the original pulp viscosity is ≤30000 mPa.s, which is in accordance with the cross-linking mechanism of the condensed-type silicone rubber, and the first sealing part 21 and the second sealing part 22 may be moisture cured at a room temperature (as shown in FIG. 14), i.e., the transition layer 3 and the adjusting gap 5 may be not provided.

In an embodiment, the sealing structure 2 includes at least one of an epoxy resin type, a polyurethane type, an acrylic acid type, and an ethylene-vinyl acetate copolymer. Meanwhile, a tensile strength of the first sealing part 21 is ≥12 Mpa, an elongation at break of the first sealing part 21 is ≥110%, and a surface adhesivity of the first sealing part 21 is ≥5 Mpa.

Exemplarily, a curing temperature of the sealing structure 2 is ≤80° C., where the curing may be heat curing, moisture curing or UV curing. After the curing is completed, the modulus of the sealing structure 2 is ≤3 MPa, the hardness is 20-85 Shore A, the CTE is ≤250 ppm/° C., and the peel force is ≥5 MPa (SUS301 interface), where SUS301 is a commonly used test material, and the adhesive dispensing precision is about 0.09 mm, which can meet the bending requirement with the bending radius of 10 mm and the bending angle of 60°~90°, and can meet the requirement with the waterproof level above 5 ATM (50 meters of water pressure).

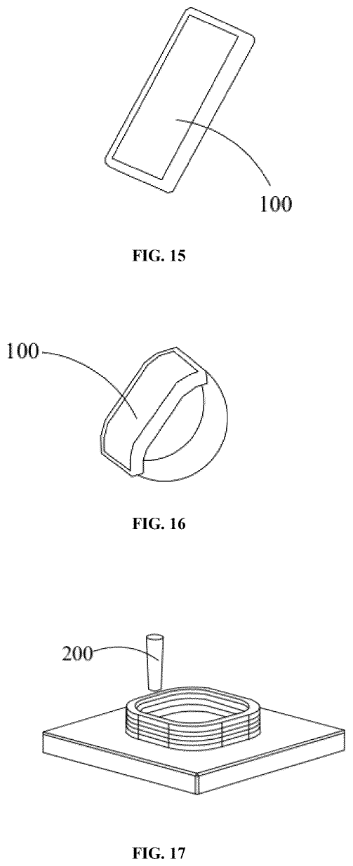

As shown in FIGS. 15-16, the embodiment of the present disclosure further provides a wearable device including the flexible display device described above. In some embodiments, the wearable device includes, but is not limited to, a watch, a bracelet, a folding screen cell phone, and the like.

The wearable device can ensure functional integrity while meeting bending requirements. The usable area of the wearable device is relatively small relative to cell phones. Electronic components may pass through the bending region 111, and the hinge of the bending region 111 may affect the sealing of the wearable device. Therefore, the sealing structure 2 can be used to perform waterproofing on the portions of the bending region 111 and the non-bending region 112 separately, meeting the bending performance requirements while waterproofing.

The embodiment further provides a manufacturing method for a flexible display device, used for manufacturing the flexible display device described above. The manufacturing method for the flexible display device includes the following steps:
bending the fanout area 13 of the flexible display panel 1 to a backlight side of the display area 11;
wrapping the transition layer 3 around the exterior of the fanout area 13; and
wrapping the sealing structure 2 around the edge of the flexible display panel 1 and around an exterior of the transition layer 3.

In an embodiment, as shown in FIG. 17, a plurality of circle layers are stacked along the third direction D3 after one circle layer is adhesive dispensed at an exterior of the flexible display panel 1 and along a circumference of the flexible display panel 1. The 3D adhesive dispensing method with a plurality of layers stacked ensures that the edge of the flexible display panel 1 and the edge of the transition layer 3 are covered with the dispensed adhesive, and the sealing is good.

Exemplarily, a thickness of a first layer of the dispensed adhesive along the third direction D3 is about 0.1205 mm to 0.3 mm, e.g., 0.05 mm, 0.1 mm, 0.2 mm, 0.25 mm, 0.3 mm, etc., and the precision is about ±0.05 to ±0.15 mm, e.g., ±0.05 mm, ±0.06 mm, ±0.07 mm, ±0.08 mm, ±0.09 mm, ±0.1 mm, etc. After the first circle of the dispensed adhesive is cured, a second layer of the dispensed adhesive is stacked on the basis of the first circle of the dispensed adhesive, and a total of 3 to 4 layers are stacked. The thickness of the bending region 111 and the thickness of the non-bending region 112 are different, the number of stacking times may be different, and the size of the dispensed adhesive per circle layer may also vary.

In an embodiment, in adhesive dispensing one circle layer, the exterior of the non-bending region 112, the exterior of the fanout area 13, and the exterior of the end area 14 are adhesive dispensed after two sides of the bending region 111 along a width direction of the flexible display panel 1 are adhesive dispensed. That is, the bending region 111 is adhesive dispensed with priority, and after the curing of the dispensed adhesive in this region is completed, the non-bending region 112 is adhesive dispensed.

Specifically, the specific adhesive dispensing steps of the manufacturing method for the flexible display device are as follows.

1. after the viscidity and rheological properties of the original pulp are tested, the parameters such as the nozzle diameter, nozzle speed, line spacing, air pressure, and layer height are initially confirmed according to relevant properties.

2. The original pulp material is introduced into the barrel 200.

3. The adhesive dispensing needle of the barrel 200 is controlled to be opened or closed through the screw rotation driven by the solenoid valve or the motor, etc.

4. The quantity of flow of the extruded adhesive is precisely controlled through the alignment platform.

5. The size and thickness of the specimen after the adhesive dispensing is completed are measured, the relevant parameters are adjusted, and the relevant precision is optimized.

6. The original pulp adhesive dispensing is performed according to the optimized process parameters, the flexible display panel 1 is horizontally placed on the carrier table, the barrel 200 performs precise adhesive dispensing along the adhesive dispensing position, the exterior of the non-bending region 112, the exterior of the fanout area 13, and the exterior of the end area 14 are adhesive dispensed after two sides of the bending region 111 along the width direction D2 are adhesive dispensed, and at the same time, at the junction position of the bending region 111 and the non-bending region 112, in an approximate 5 mm to 10 mm range, adhesive dispensing is performed on the overlapped region, enabling that the edge of the entire flexible display panel 1 is covered with the dispensed adhesive, and ensuring the sealing.

7. A plurality of circle layers are stacked along the third direction D3 after one circle layer is adhesive dispensed at the exterior of the flexible display panel 1 and along the circumference of the flexible display panel 1.

It should be understood that the present disclosure does not limit its application to the detailed structure and arrangement manner of the components proposed in this specification. The present disclosure can have other embodiments and can be implemented and performed in a variety of ways. The foregoing deformations and modifications fall within the scope of the present disclosure. It should be understood that the present disclosure, as disclosed and limited in this specification, extends to all alternative combinations of two or more individual features mentioned or apparent in the text and/or the accompanying drawings. All of these different combinations constitute a plurality of alternative aspects of the present disclosure. The embodiments described in this specification illustrate the best ways known for implementing the present disclosure and will enable those skilled in the art to utilize the present disclosure.

1. A flexible display device, comprising:
a flexible display panel, wherein the flexible display panel is provided with a display area and a peripheral area, the peripheral area is provided at a periphery of the display area in a surrounding manner, and a fanout area is provided at a side of the peripheral area away from the display area along a first direction;
a sealing structure, wrapped around an edge of the flexible display panel; and
at least one transition layer, wrapped around an exterior of the fanout area, wherein the transition layer is provided between the fanout area and the sealing structure.

2. The flexible display device according to claim 1, wherein a modulus of the transition layer is less than a modulus of a portion of the sealing structure corresponding to the fanout area;
a thickness of the transition layer is less than a thickness of a portion of the sealing structure corresponding to the fanout area; or
a modulus of the transition layer is less than a modulus of a portion of the sealing structure corresponding to the fanout area, and a thickness of the transition layer is less than a thickness of the portion of the sealing structure corresponding to the fanout area.

3. The flexible display device according to claim 1, wherein a modulus of the transition layer is 0.5 Mpa to 3 Mpa, and a modulus of a portion of the sealing structure corresponding to the fanout area is 3 Mpa to 10 Mpa;
a thickness of the transition layer is 0.05 mm to 0.3 mm, and a sum of a thickness of a portion of the sealing structure corresponding to the fanout area and the thickness of the transition layer is 0.3 mm to 0.5 mm; or
a modulus of the transition layer is 0.5 Mpa to 3 Mpa, a modulus of a portion of the sealing structure corresponding to the fanout area is 3 Mpa to 10 Mpa, a thickness of the transition layer is 0.05 mm to 0.3 mm, and a sum of a thickness of the portion of the sealing structure corresponding to the fanout area and the thickness of the transition layer is 0.3 mm to 0.5 mm.

4. The flexible display device according to claim 1, wherein the at least one transition layer comprises a plurality of transition layers, and moduli of the plurality of the transition layers are gradually increased along the first direction and along a direction from the fanout area to the sealing structure;
the at least one transition layer comprises a plurality of transition layers, and thicknesses of the plurality of the transition layers are gradually increased along the first direction and along a direction from the fanout area to the sealing structure; or
the at least one transition layer comprises a plurality of transition layers, moduli of the plurality of the transition layers are gradually increased along the first direction and along a direction from the fanout area to the sealing structure, and thicknesses of the plurality of the transition layers are gradually increased along the first direction and along the direction from the fanout area to the sealing structure.

5. The flexible display device according to claim 1, wherein the transition layer comprises a thermoplastic-type material of a polyacrylate type.

6. The flexible display device according to claim 1, further comprising:
a protective layer, wrapped around the exterior of the fanout area, wherein the protective layer is provided between the fanout area and the transition layer.

7. The flexible display device according to claim 1, wherein an end area is provided at a side of the flexible display panel away from the fanout area along the first direction, the display area comprises a bending region and a non-bending region, and the bending region and the non-bending region are arranged along the first direction; and
an adjusting gap is provided between the end area and the sealing structure.

8. The flexible display device according to claim 7, wherein the adjusting gap is positively correlated with a length of the bending region, the adjusting gap is positively correlated with a bending angle of the bending region, and the adjusting gap is negatively correlated with a bending radius of the bending region.

9. The flexible display device according to claim 7, wherein a groove is provided at a side of the sealing structure facing the end area.

10. The flexible display device according to claim 1, wherein the display area comprises a bending region and a non-bending region, and the bending region and the non-bending region are arranged along the first direction; and
the sealing structure comprises:
a first sealing part, provided at at least one side of the display area along a second direction, wherein the first sealing part is provided in correspondence with the bending region, and the second direction is perpendicular to the first direction; and
a second sealing part, provided at at least one side of the display area along the second direction, wherein the second sealing part is provided in correspondence with the non-bending region;
wherein a modulus of the first sealing part is less than a modulus of the second sealing part; a thickness of the first sealing part is less than a thickness of the second sealing part; or a modulus of the first sealing part is less than a modulus of the second sealing part, and a thickness of the first sealing part is less than a thickness of the second sealing part.

11. The flexible display device according to claim 10, wherein the modulus of the first sealing part is 0 to 3 Mpa, and the modulus of the second sealing part is 3 Mpa to 20 Mpa.

12. The flexible display device according to claim 10, wherein a tensile strength of the first sealing part is greater than or equal to 12 Mpa, an elongation at break of the first sealing part is greater than or equal to 110%, and a surface adhesivity of the first sealing part is greater than or equal to 5 Mpa.

13. The flexible display device according to claim 1, wherein the sealing structure comprises an organopolysiloxane polymer-type material, a silica filler, a silane adhesion promoter, and a catalyst; or
the sealing structure comprises at least one of an epoxy resin type, a polyurethane type, an acrylic acid type, or an ethylene-vinyl acetate copolymer.

14. The flexible display device according to claim 1, wherein the fanout area comprises a bending part and a connecting part, one end of the bending part is connected to the display area, another end of the bending part is connected to the connecting part, the bending part and the connecting part are arranged along a third direction, and the third direction and the first direction are perpendicular to each other;
the flexible display device further comprises a supporting layer, and the supporting layer is provided between the display area and the connecting part; and
an activity cavity is formed between a side of the supporting layer and a side of the fanout area that are close to each other.

15. The flexible display device according to claim 14, wherein the flexible display panel further comprises:
a cover layer, provided at a side of the display area away from the connecting part along the third direction; wherein
an orthographic projection of the cover layer relative to the display area is located outside an orthographic projection of the sealing structure relative to the display area, and the orthographic projection of the cover layer relative to the display area is located outside an orthographic projection of the transition layer relative to the display area.

16. A wearable device, comprising a flexible display device, wherein the flexible display device comprises:
a flexible display panel, wherein the flexible display panel is provided with a display area and a peripheral area, the peripheral area is provided at a periphery of the display area in a surrounding manner, and a fanout area is provided at a side of the peripheral area away from the display area along a first direction;
a sealing structure, wrapped around an edge of the flexible display panel; and
at least one transition layer, wrapped around an exterior of the fanout area, wherein the transition layer is provided between the fanout area and the sealing structure.

17. A manufacturing method for a flexible display device, used for manufacturing a flexible display device, wherein the flexible display device comprises:
a flexible display panel, wherein the flexible display panel is provided with a display area and a peripheral area, the peripheral area is provided at a periphery of the display area in a surrounding manner, and a fanout area is provided at a side of the peripheral area away from the display area along a first direction;
a sealing structure, wrapped around an edge of the flexible display panel; and
at least one transition layer, wrapped around an exterior of the fanout area, wherein the transition layer is provided between the fanout area and the sealing structure; and
the manufacturing method for the flexible display device comprises:
bending the fanout area of the flexible display panel to a backlight side of the display area;
wrapping the transition layer around the exterior of the fanout area; and
wrapping the sealing structure around the edge of the flexible display panel and around an exterior of the transition layer.

18. The manufacturing method for the flexible display device according to claim 17, wherein the wrapping the sealing structure around the edge of the flexible display panel and around the exterior of the transition layer comprises:
stacking a plurality of circle layers along a third direction after one circle layer is adhesive dispensed at an exterior of the flexible display panel and along a circumference of the flexible display panel.

19. The manufacturing method for the flexible display device according to claim 18, wherein in adhesive dispensing one circle layer, an exterior of a non-bending region, the exterior of the fanout area, and an exterior of an end area are adhesive dispensed after two sides of a bending region along a width direction of the flexible display panel are adhesive dispensed.

20. The flexible display device according to claim 10, wherein the thickness of the first sealing part is 0.05 mm to 0.1 mm, and the thickness of the second sealing part is 0.1 mm to 0.2 mm.
